(19) United States
(12) Patent Application Publication
(10) Pub. No.: US 2019/0368070 A1
(43) Pub. Date: Dec. 5, 2019

(54) METHOD FOR PRODUCING HOMOEPITAXIAL DIAMOND LAYERS

(71) Applicant: Fraunhofer-Gesellschaft zur Förderung der angewandten Forschung e.V., Munich (DE)

(72) Inventors: Verena Zürbig, Freiburg (DE); Christoph E. Nebel, Freiburg (DE)

(73) Assignee: Fraunhofer-Gesellschaft zur Förderung der angewandten Forschung e.V., Munich (DE)

(21) Appl. No.: 16/426,093

(22) Filed: May 30, 2019

(30) Foreign Application Priority Data
Jun. 1, 2018 (DE) 10 2018 208 692.3

(51) Int. Cl. C30B 29/04; C30B 25/04; C30B 25/10; C30B 25/20; C30B 30/02; C30B 29/60; C30B 29/66

(52) U.S. Cl. CPC C30B 29/04; C30B 25/04; C30B 25/10; C30B 29/66; C30B 30/02; C30B 29/605; C30B 25/20

(57) ABSTRACT

A method for producing homoepitaxial diamond layers is provided. A substrate comprising diamond and having a first side and an opposite second side is provided, at least the first side having a [100] orientation. Protruding structures are provided on the first side by masking and subsequently etching the substrate. Diamond is deposited from an activated process gas on the first side of the substrate, wherein pyramids are produced around the protruding structures, the side faces of which are at least partially [111]-oriented.

### RELATED APPLICATIONS

This application is related to and claims priority under 35 USC § 119 to German Patent Application Serial No. 102018208692.3 filed on Jun. 1, 2018. The subject matter disclosed in that application is hereby expressly incorporated into the present application in its entirety.

### FIELD OF THE DISCLOSURE

The invention relates to a method for producing epitaxial diamond layers, comprising the following steps: providing a substrate having a first side and an opposite second side and depositing diamond from an activated process gas on the first side of the substrate.

### BACKGROUND

US 2010/012491 A discloses a monocrystalline, boron-doped diamond substrate. Said substrate is overgrown by a boron-doped single-crystalline diamond layer deposited from an activated process gas at low pressure. This known method provides single-crystalline diamond layers having a crystallographic [100] orientation only. This known solution has the drawback that the solubility of dopants into the growing crystal and therefore the conductivity of the grown material as well are inadequate.

Therefore, there is a need for a method for producing homoepitaxial diamond layers which may provide large-area conductive diamond layers with a high dopant concentration.

### SUMMARY

The object is solved by a method for producing homoepitaxial diamond layers, said method comprising the following steps: Providing a substrate comprising diamond or consisting of diamond and having a first side and an opposite second side, wherein at least the first side has a [100] orientation; producing a plurality of protruding structures on the first side by masking and subsequently etching the substrate; depositing diamond from an activated process gas on the first side of the substrate, wherein pyramid-like structures are produced around the protruding structures, the side faces of which are at least partially [111]-oriented.

### BRIEF DESCRIPTION OF THE DRAWINGS

FIG. 1 illustrates a sectional view of a substrate after having carried out a first method step.

FIG. 2 illustrates a sectional view of the substrate after having carried out a second method step.

FIG. 3 illustrates a sectional view of the substrate after having carried out a third method step.

FIG. 4 illustrates a top view of the substrate after having carried out the third method step.

FIG. 5 illustrates an isometric drawing of the substrate after having carried out the third method step.

FIG. 6 illustrates aspects of the third method step.

### DETAILED DESCRIPTION

According to one embodiment of the invention, a substrate is provided comprising diamond. According to another embodiment of the invention, a substrate is provided consisting of diamond. Said substrate may comprise at least one dopant such as nitrogen or phosphorous or boron. Said substrate forms a basis for the production of homoepitaxial diamond layers. In some embodiments, the substrate may be a natural diamond crystal. In other embodiments, HPHT (high pressure-high temperature) diamond crystal may be used. In still another embodiment of the invention, the substrate may comprise heteroepitaxially deposited, polycrystalline, nanocrystalline or monocrystalline diamond. Thus, the substrate according to the invention comprises a base material being covered by heteroepitaxially deposited diamond. In these embodiments, the base material used to produce the diamond substrate may still be present in the substrate used when carrying out the invention. In other embodiments of the invention, the base material may have been removed before carrying out the method according to the invention. In these embodiments, the base material may be removed by any of mechanical polishing, micro-milling, wet chemical etching and/or dry chemical etching.

The diamond substrate or the diamond layer of a more complex substrate may have a thickness of more than about 1 μm or more than about 20 μm or more than about 50 μm or more than about 100 μm or more than about 500 μm. In some embodiments of the invention, the diamond substrate or the diamond layer of a more complex substrate may have a thickness of less than about 600 μm or less than about 200 μm or less than about 100 μm or less than about 50 μm.

The substrate has a first side and an opposite second side. The first and/or second side may be selected to be the sides with the largest surface area of the substrate. At least the first side may be polished and thus have an RMS roughness of less than about 100 μm or less than about 50 μm or less than about 10 μm or less than about 1 μm. The opposite second side may also be optionally polished or remain rough, i.e. untreated.

Within the meaning of the present description, the crystallographic directions are described using Miller indices, which indicate how many of the three axes of a Cartesian coordinate system are intersected by a given crystal plane. For example, a plane of a cube only intersects one axis and is therefore described by the Miller indices 1, 0 and 0 (short: [100]), i.e. the plane intersects one axis and runs parallel to the other two axes. A dodecahedral plane intersects two axes and runs parallel to one axis. It is therefore described by the Miller indices [110]. An octahedral surface or tetrahedral surface intersects all three axes and is therefore described by the Miller indices [111].

At least the first side of the substrate may have a [100] orientation. Such a substrate showing a [100] oriented surface on its first side has the advantage that such substrates may be easily produced and thus are available on a large scale and at low cost. For the purposes of the present description, the first side of the substrate shall be regarded to have a [100] orientation even if the oriented crystal plane deviates less than about 10° or less than about 5° or less than about 2° from the orientation of the first side of the substrate as defined by its normal vector.

According to the invention, a plurality of protruding structures is produced at least on the first side of the substrate. Producing said protruding structures may include the step of depositing a masking layer, such as a photoresist, on the first side of the substrate. The masking layer may be applied over the entire surface and subsequently partially removed by partial exposure to light, processing and etching, so that the masking layer is only applied to partial areas of the first side of the substrate. In other embodiments of the invention, the masking layer may comprise any of a photoresist or a hard mask or a metal or an alloy. Subsequently, the substrate may be subject to a wet chemical etching or a dry chemical etching step. This causes first parts of the first side of the substrate to be removed. Second parts of the first side covered by the masking layer are protected from being etched, thus creating protruding structures on the first side of the substrate.

In the next method step, diamond is deposited from an activated process gas on at least a partial surface of the first side of the substrate, thus growing pyramids around the protruding structures, the side faces of which are at least partially [111]-oriented. At least one dopant may be added to the diamond layer during growth. As explained previously, the side faces of the pyramids shall be regarded to have a [111] orientation even if the [111] oriented crystal plane deviates less than about 10° or less than about 5° or less than about 2° from the orientation of the respective side face of the pyramid as defined by its normal vector.

The [111]-oriented diamond surfaces produced by this method may have an increased solubility for common dopants compared to the original [100]-oriented first side of the substrate. Thus, the diamond layer produced according to the invention may have a higher doping concentration, thereby exhibiting a higher electrical conductivity and/or a higher charge carrier density compared to an [100]-oriented diamond layer. If the dopant added during diamond growth results in the generation of NV centers, the method provided by the invention may have the advantage that said NV centers are at least partially oriented in the [111] direction, thereby promoting the emission of light in this direction.

In some embodiments, the diamond may be deposited from an activated process gas at a pressure between from about 50 mbar to about 300 mbar. The process gas comprises at least hydrogen and a gas comprising carbon. In some embodiments, said gas comprising carbon may be selected to comprise at least one hydrocarbon, more specifically any of methane, ethane and/or acetylene. In some embodiments, said activated process gas may comprise a dopant.

In some embodiments, the process gas used for diamond deposition may be activated by microwave radiation. In other embodiments of the invention, a filament made of a refractory metal may be used for activation by heating said filament to an elevated temperature. In still another embodiment, the process gas may be activated by radio frequency radiation, i.e. electromagnetic radiation having a frequency selected from about 20 kHz to about 20 MHz. In some embodiments, the substrate may be heated to an elevated temperature and/or a bias voltage may be applied at least temporarily to the substrate during diamond deposition.

In known diamond deposition methods, depositing diamond from an activated process gas on a [100]-oriented diamond surface leads to the growth of [100]-oriented diamond. The inventors of the current invention realized that forming protruding structures on a [100]-oriented surface of a diamond substrate prior to diamond deposition from an activated process gas leads to the growth of [111]-oriented areas or facettes on this substrate surface. Said [111]-oriented areas or facettes offer extended uses of the grown diamond due to increased dopant concentration. The same result may be obtained by depositing diamond from an activated process gas on a [111]-oriented diamond substrate. However, these substrates offer smaller surface area compared to [100]-oriented substrates. It may be an advantage of the invention to provide [111]-oriented areas on a large scale.

In some embodiments, the substrate may have a diameter of more than 2 cm or more than 5 cm or more than 10 cm. In some embodiments, the substrate may have a perimeter of more than 2 cm or more than 5 cm or more than 10 cm. In some embodiments, the substrate may be selected to be polygonal, in particular rectangular or square. In some embodiments, the substrate may comprise a monocrystalline diamond crystal having a first side having 3 mm×3 mm or 4 mm×4 mm or 8 mm×8 mm in size. In other embodiments, the length of at least one edge may be selected from about 3 mm to about 8 mm.

In some embodiments, the protruding structures on the substrate may be produced at such a distance and/or such a height that the base edges of adjacent pyramids touch each other at least partially. This feature may lead to an almost complete coverage of the first side of the substrate with [111]-oriented diamond surfaces.

In some embodiments, etching of the first side of the diamond substrate may be done in a plasma comprising at least any of argon and/or oxygen plasma. Etching in said plasma may be carried out at a pressure selected from about 0.2 Pa to about 0.9 Pa. In some embodiments of the invention, a bias voltage selected from about −100 V to about −180 V may be applied during etching at least temporarily.

In some embodiments, the cross-section of said protruding structures may be polygonal or round. The protruding structures may have a length measured in at least one direction within the plane defined by the substrate ranging from about 100 nm to about 500 nm or of about 150 nm to about 250 nm. In some embodiments of the invention, the protruding structures may have a circular cross-section each, thereby allowing the growth of equilateral pyramids having an approximately square base.

In some embodiments, the activated process gas may comprise at least hydrogen and methane during the deposition of the diamond, the concentration of methane being selected between about 2% and about 5% or between about 2.1% and about 3% by volume. This allows an α-parameter of more than about 2.8 or more than about 2.9 or more than about 3.0 to be achieved. The α-parameter indicates the volume ratio of the growing [100]-oriented diamond to the volume of the [111]-oriented diamond:

$$α = \sqrt{3} \frac{{V}_{( 100 )}}{{V}_{( 111 )}}$$

Thus, a high α-parameter promotes the growth of the [111]-oriented areas or facettes of the pyramids and may be preferred in some embodiments.

In some embodiments, the substrate may have a temperature being selected from about 800° to about 900° or between about 830° and about 870° during diamond deposition. Along with the methane content of the process gas, the temperature is the second, important parameter for setting the α-parameter to a desired value. In said temperature range, particularly advantageous properties of the grown diamond may be achieved.

In some embodiments, the protruding structures may have a height measured from the substrate surface to the tip of a respective structure ranging from about 2 μm to about 4 μm. In some embodiments, the protruding structures may have a height measured from the substrate surface to the tip of a respective structure ranging from about 3 times or about 2.8 to about 2.9 times or about 2.82 times the distance of adjacent protruding structures. This feature may allow to grow adjacent pyramids touching each other at their respective baselines, thereby obtaining a complete coverage of the first side of the substrate by said pyramids having [111]-oriented facettes.

In some embodiments, the total area of the first side of the substrate may be increased by a factor of 1.5 to 1.73 by growing said diamond layer having the pyramid-like structure. Thus, not only the advantageously usable [111]-oriented crystallographic direction is available on the original surface area of the substrate, but also an overall enlarged surface area is formed. This feature may allow a higher packing density of electronic components on the substrate.

In some embodiments of the invention, the protruding structures may be arranged in a regular grid-like pattern on the first side of the substrate. Such an arrangement may allow the complete covering of the first side of the substrate with the pyramid-like structure of said diamond layer. This feature may provide for a maximum yield of the [111]-oriented facettes on the first side of the substrate.

In some embodiments of the invention, the activated process gas may comprise at least temporarily at least one dopant. Such a dopant may be selected from any of boron, silicon, phosphorus, silicon, germanium and/or nitrogen. In some embodiments, the grown diamond layer may show a p-type conductivity or an n-type conductivity depending on the dopant selected. In other embodiments, the at least one dopant may lead to at least one optically active center, for example an NV center, a SiV center or a GeV center.

In some embodiments, the activated process gas may comprise at least one first dopant in a first method step during the deposition of the diamond and comprise at least one second dopant in a second method step following in time. In some embodiments of the invention, the first dopant may be different from the second dopant. In some embodiments of the invention, the second dopant may also be omitted, thereby leading to a doped diamond layer followed by an undoped or not intentionally doped diamond layer. In some embodiments, these first and second method steps may be carried out several times in sequence. This allows the production of at least one pn-junction, at least one pin-junction or, with cyclic repetition, even more complex components, such as Bragg filters or bipolar transistors. Due to the large band gap of the diamond, such components are particularly suitable for high temperature and/or high power applications.

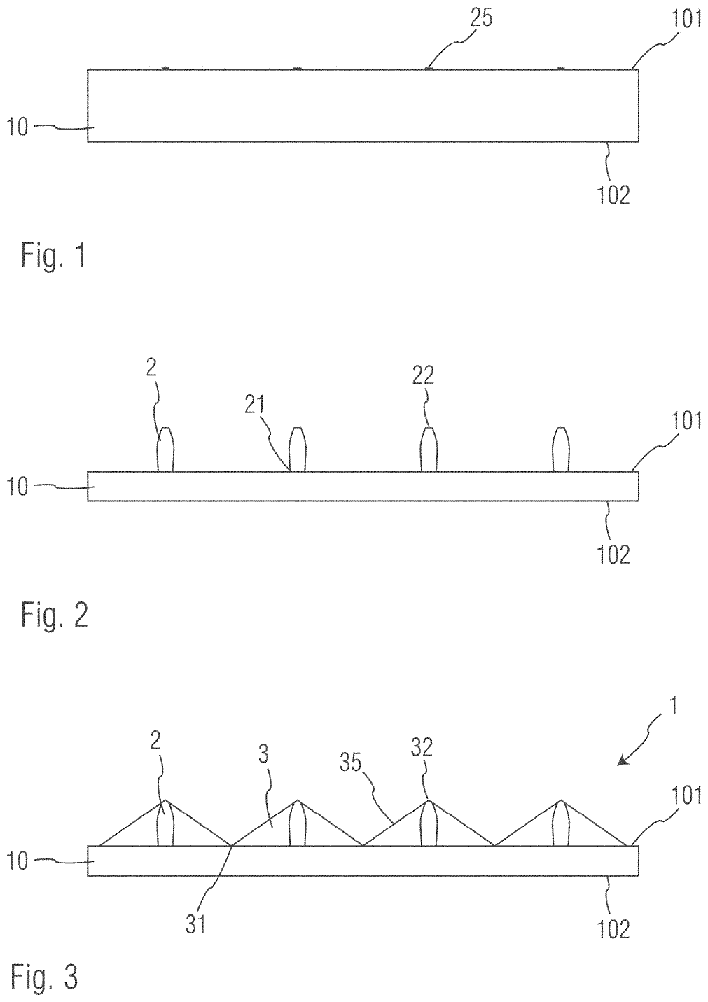

The invention shall be explained in more detail below on the basis of the attached drawings without limiting the general inventive concept, wherein FIGS. 1 to 3 illustrate some method steps which might be useful when carrying out the invention. The figures show a section view of a substrate 10 having a first side 101 and an opposite second side 102 after having performed a first, a second and a third method step.

FIG. 1 illustrates a substrate 10 comprising diamond. The substrate 10 has a first side 101 and an opposite second side 102. The substrate 10 may be or comprise monocrystalline or nanocrystalline or polycrystalline diamond. The diamond may be deposited on a base material (not shown), for example by low-pressure synthesis from an activated process gas on silicon. The base material may optionally be removed before subsequent method steps are carried out, e.g. by etching or machining. In other embodiments, the base material may remain as a part of the substrate 10.

In other embodiments of the invention, the substrate 10 may be an HPHT diamond or a natural diamond. In these embodiments, the diamond may be glued or brazed on a base material or the substrate 10 may not comprise a base material at all.

The first side 101 of the substrate 10 has a [100] orientation. In some embodiments, the roughness of the first side 101 of the substrate 10 may be smoothened by any of plasma etching or mechanical polishing in order to provide a substrate surface having a predeterminable roughness.

As also shown in FIG. 1, a masking layer 25 is applied to the first side 101 having openings at regular distances. The masking layer 25 may comprise or consist of any of a photoresist, a metal and/or an alloy. In other embodiments, a hard masking made of any of a metal, an alloy, a nitride, an oxide and/or an oxynitride may be structured by means of a photoresist. Said photoresist may be partially removed by any of optical lithography or electron beam lithography. The structured mask 25 shown in FIG. 1 may be arranged in the form of elongated stripes or round or polygonal dots in a regular or grid-like pattern on the first side 101 of the substrate 10.

In the following second method step, at least the first side 101 of the substrate 10 is subject to at least one wet or dry chemical etching step. As an example, dry chemical etching may be performed in a plasma comprising argon and oxygen at a pressure ranging from about 0.5 Pa to about 0.7 Pa. In some embodiments, an optional negative bias voltage is applied to the substrate 10. This bias voltage may be selected from about −100 V to about −180 V.

As shown in FIG. 2, said chemical etching at least partially removes diamond material from the first side 101 of the substrate 10. Protruding structures 2 form at locations defined by said masking layer 25. Said protruding structures 2 have a base 21 forming the contact to the first side 101 of the substrate 10. Each protruding structure 2 has a tip 22 opposite to said base 21. The protruding structures 2 are arranged approximately perpendicular to the first side 101 of the substrate 10, i.e. approximately parallel to the normal vector of the substrate 10.

The cross-section of the individual protruding structures 2 may be polygonal or round. In some embodiments of the invention, the protruding structures may be individual columns, depending on form of the masking layer 25 applied previously. In other embodiments of the invention, the protruding structures may form elongated stripes on the first side 101 of the substrate 10. In some embodiments of the invention, the height of the individual protruding structures 2 may be selected from about 2 μm to about 4 μm. The height of the protruding structures 2 may be selected to be about 2.8 times the distance of adjacent protruding structures 2.

In a third method step, the substrate 10 as shown in FIG. 2 having said protruding structures 2 is overgrown with diamond from an activated process gas in a low-pressure diamond synthesis. The third method step may comprise inserting the substrate 10 into a reactor vessel which is subsequently being filled with a process gas comprising at least one precursor. In some embodiments, the process gas may comprise hydrogen and methane and at least one optional dopant. The process gas may have a pressure inside the reactor vessel from about 150 mbar to about 250 mbar. The methane content within the process gas may be selected from about 2% to about 5% or from about 2.1% to about 3%. In some embodiments, the process gas is activated by microwave radiation, which partly ionizes the process gas, thereby dissociating the molecular components of the process gas at least partially. The substrate may optionally be heated and/or a bias voltage may be applied thereto in orer to promote diamond growth on the substrate.

As may be best seen from FIGS. 3, 4, and 5, the protruding structures 2 promote a pyramid-like shape of the growing diamond layer, i.e. the diamond forms a plurality of pyramids 3. The pyramids 3 have side faces 35 having a [111] orientation. In the case of equilateral pyramids, they form approximately square base areas on the first side 101 of the substrate 10. The square base areas are limited by base edges 31. The base edges of neighboring pyramids 3 may touch one another at least partially, so that the visual impression of a complete covering of the first side 101 of the substrate 10 with pyramids 3 results.

The pyramids 3 have the effect that the surface area of the first side 101 of the substrate 10 is enlarged by a factor of about 1.5 to about 1.73. In addition, the side faces 35 have a [111] orientation in contrast to the original [100] orientation of the first side 101 of the substrate 10. This may improve doping from the process gas since the [111]-oriented diamond surface has a solubility for dopants being a factor of about 10 higher compared to a [100]-orientated surface.

Deposition of the diamond layer in the third method step from an activated process gas may comprise a plurality of sequential steps. Each of these sequential steps may differ from a preceding step by using any of a different process gas, a different gas pressure, a different bias voltage and/or a different microwave power. This leads to the growth of different diamond layers having different properties such as different doping. The doping may differ with respect to any of type and concentration. For example, a p-doped layer may be grown on top of an n-doped layer, so that a pn-diode or a pin-diode may be provided. Optionally, a nominally undoped diamond layer may be grown between a p-doped layer and an n-doped layer, so that a pin-diode may be provided. In other embodiments of the invention, weakly doped layers may be deposited on higher doped layers of the same conductivity or a multitude of differently doped layers may be deposited on top of one another to thus produce more complex components such as Bragg gratings or bipolar transistors.

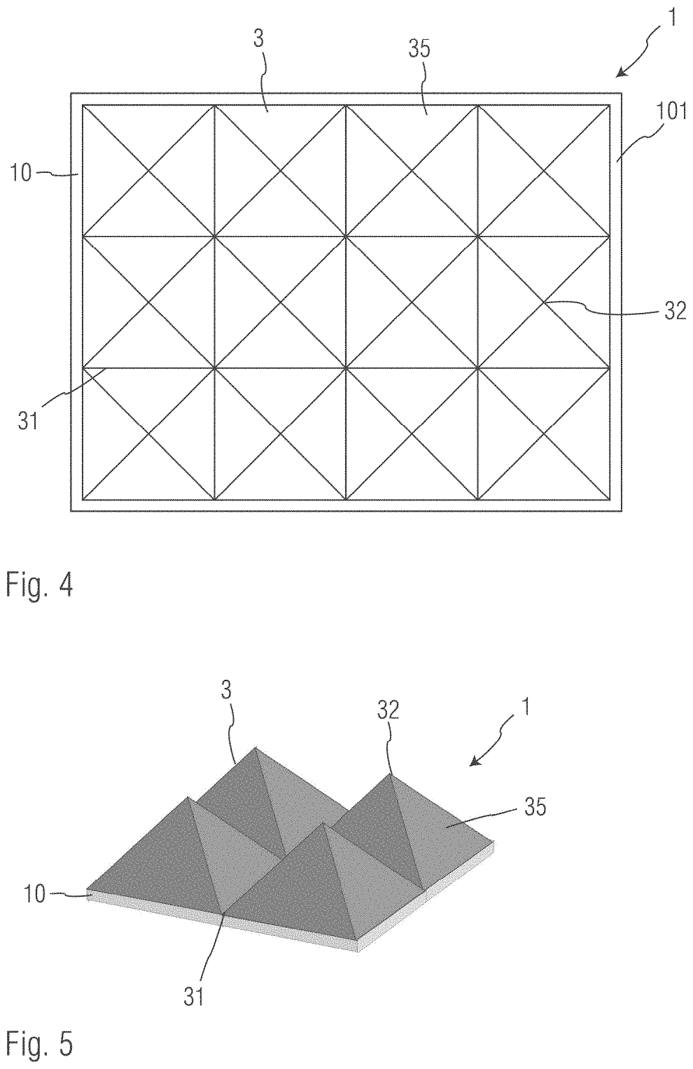

FIGS. 4 and 5 illustrate the substrate 10 after carrying out the method according to the invention. FIG. 4 shows a plan view of the substrate 10. FIG. 5 shows an isometric representation. It may apparent that a pyramid-like structure 3 is formed around each of the protruding structures 2. Adjacent pyramids 3 touch one another at their base edges 31. As a result, the entire surface or at least a substantial part of the surface of the first side 101 of the substrate 10 is covered with pyramids 3. Their side faces 35 have a [111] orientation, which may be postprocessed to obtain at least one device suitable for electronic or electrochemical applications. In contrast to known [111]-oriented substrates, the invention allows for the first time to provide large [111]-oriented diamond surfaces.

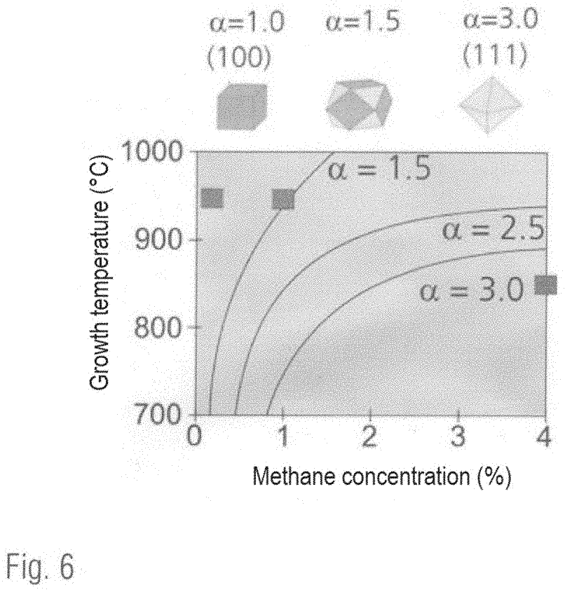

FIG. 6 shows the change in the α-parameter depending on the growth temperature of the substrate 10 and the methane concentration in the process gas during the deposition of diamond in the third method step according to the present invention. The α-parameter is defined as the ratio of the volume of [111]-oriented diamond to the volume of [100]-oriented diamond. A high α-parameter thus leads to the growth of predominantly [111]-oriented diamond, whereas a low α-parameter leads to the growth of predominantly [100]-oriented diamond. Since the pyramids proposed according to the invention shall have side faces 35, which are predominantly [111]-oriented, a comparatively high α-parameter is aimed at during the deposition of diamond. This is achieved by a comparatively high methane concentration of more than 2% or more than 3% or more than 4% and a substrate temperature of about 800° C. to about 900° C. FIG. 6 shows that the lower the methane concentration in the process gas is chosen, the lower the temperature of the substrate 10 is advantageously chosen. The methane concentration given here represents a volume concentration.

While the disclosure has been described in this detailed description, the same is to be considered as exemplary and not restrictive in character, it being understood that only illustrative embodiments thereof have been described and that changes and modifications that come within the spirit of the disclosure are desired to be protected. If the claims and the above description define “first” and “second” features, this designation is used to distinguish between two similar features without determining a ranking. The following claims are to be understood in such a way that a stated feature is present in at least one embodiment of the invention. This does not exclude the presence of additional features.

1. A method for producing homoepitaxial diamond layers, comprising:
providing a substrate comprising diamond and having a first side and an opposite second side, at least the first side having a [100] orientation,
producing a plurality of protruding structures on the first side by masking and subsequently etching the substrate,
depositing diamond from an activated process gas on the first side of the substrate, wherein pyramids are produced around the protruding structures, the side faces of which are at least partially [111]-oriented.

2. The method of claim 1, wherein base edges of adjacent pyramids at least partially contact one another.

3. The method of claim 1, wherein during the deposition of the diamond the activated process gas comprises at least hydrogen and methane, the proportion of methane being between about 2% and about 5%.

4. The method of claim 1, wherein during deposition the substrate has a temperature between about 800° C. and about 900° C.

5. The method of claim 1, wherein during deposition the substrate has a temperature between about 830° C. and about 870° C.

6. The method of claim 1, wherein the protruding structures have a height of about 2 μm to about 4 μm.

7. The method of claim 1, wherein the protruding structures are arranged in a regular grid-like pattern.

8. The method of claim 1, wherein the area of the first side of the substrate is increased by about a factor of 1.5 to 1.73 by applying the pyramids.

9. The method of claim 1, wherein the first side of the substrate is completely covered with pyramids.

10. The method of claim 1, wherein the height of the protruding structures corresponds to about 2.5 to about 3 times the distance of adjacent protruding structures.

11. The method of claim 1, wherein the activated process gas comprises at least one dopant when depositing the diamond.

12. The method of claim 11, wherein when depositing the diamond the activated process gas comprises at least a first dopant in a first method step and comprises at least a second dopant in a second method step following in time

13. The method of claim 11, wherein the dopant is selected from the group comprising boron, silicon, phosphorus, silicon, germanium and nitrogen.

14. The method of claim 1, wherein an α-parameter is higher than about 2.8.

15. A method for producing homoepitaxial diamond layers, comprising:
providing a substrate comprising diamond and having a first side and an opposite second side, at least the first side having a [100] orientation,
producing a plurality of protruding structures on the first side by masking and subsequently etching the substrate,
depositing diamond from an activated process gas on the first side of the substrate, wherein pyramids are produced around the protruding structures, the side faces of which are predominantly [111]-oriented.

16. The method of claim 15, wherein an α-parameter is higher than about 2.8.

17. The method of claim 15, wherein during deposition the substrate has a temperature between about 830° C. and about 870° C.

18. The method of claim 15, wherein the protruding structures have a height of about 2 μm to about 4 μm.

19. The method of claim 15, wherein the protruding structures are arranged in a regular grid-like pattern.

20. The method of claim 15, wherein the area of the first side of the substrate is increased by about a factor of 1.5 to 1.73 by applying the pyramids.

21. The method of claim 15, wherein the height of the protruding structures corresponds to about 2.5 to about 3 times the distance of adjacent protruding structures.

22. The method of claim 15, wherein the activated process gas comprises at least temporarily at least one dopant.

23. The method of claim 22, wherein the dopant is selected from the group comprising boron, silicon, phosphorus, silicon, germanium and nitrogen.
